(19) United States
(12) Patent Application Publication
(10) Pub. No.: US 2011/0313692 A1
(43) Pub. Date: Dec. 22, 2011

(54) Enhanced Intelligent Patch Panel Diagnostic Management

(75) Inventors: Wael William Diab, San Francisco, CA (US); Scott Powell, Alisa Viejo, CA (US)

(73) Assignee: Broadcom Corporation, Irvine, CA (US)

(21) Appl. No.: 12/819,361

(22) Filed: Jun. 21, 2010

(51) Int. Cl. G01R 31/02; G06F 1/26; G06F 15/00

(52) U.S. Cl. 702/59; 702/183; 700/295

(57) ABSTRACT

A system and method for enhanced intelligent patch panel diagnostic management. Physical layer device technology can be implemented into a patch panel to perform diagnostics of a communication channel. This diagnostic information (e.g., length of cable, location of cable fault, type of cable, etc.) can be displayed on a display of the patch panel management system to assist IT personnel.

### BACKGROUND

1. Field of the Invention

The present invention relates generally to data communication networks and, more particularly, to enhanced intelligent patch panel diagnostic management.

2. Introduction

Large installations of data communication equipment (e.g., routers, switches, servers, etc.) are common in service provider, enterprise, or data center environments. The network topology and functionality implemented in such environments are constantly evolving as the installations are adapted to meet ever-changing needs. Regardless of the particulars of such installations, management of the complex infrastructure is a key component of its effectiveness.

Organization of such installations are key to ensuring that the computing resources function in a cost-effective manner. One aspect of such an organization effort is cable management. As would be appreciated, a data center environment that houses thousands or tens of thousands of servers requires a cabling infrastructure that can be equally as challenging as the servers themselves. A proper cabling management program is therefore a key component of any operations, administration, maintenance and provisioning program. Efficiency of the cabling management program ideally results in substantial savings in time and resources.

Patch panels play a key role in any large installation of data communication equipment. Patch panels are designed to enforce a structured organization in the layout and connectivity of data communication equipment. What is needed therefore is a patch panel management system that adds value to the IT personnel in administrating operations, administration, maintenance and provisioning efforts.

### SUMMARY

A system and/or method for enhanced intelligent patch panel diagnostic management, substantially as shown in and/or described in connection with at least one of the figures, as set forth more completely in the claims.

### BRIEF DESCRIPTION OF THE DRAWINGS

In order to describe the manner in which the above-recited and other advantages and features of the invention can be obtained, a more particular description of the invention briefly described above will be rendered by reference to specific embodiments thereof which are illustrated in the appended drawings. Understanding that these drawings depict only typical embodiments of the invention and are not therefore to be considered limiting of its scope, the invention will be described and explained with additional specificity and detail through the use of the accompanying drawings in which:

FIG. 1 illustrates an example topology for a link.

FIG. 2 illustrates an embodiment of a patch panel management system.

FIG. 3 illustrates an embodiment of a physical layer device in a patch panel management system.

FIG. 4 illustrates a flowchart of a process of the present invention.

FIG. 5 illustrates an example of an additional embodiment of a patch panel management system.

### DETAILED DESCRIPTION

Various embodiments of the invention are discussed in detail below. While specific implementations are discussed, It should be understood that this is done for illustration purposes only. A person skilled in the relevant art will recognize that other components and configurations may be used without parting from the spirit and scope of the invention.

Patch panels are valuable in that they assist IT personnel in making fast and simple changes in the interconnections between various types of network equipment (e.g., switches, servers, etc.). These interconnections are based on large numbers of patch cords and cables that link the network equipment.

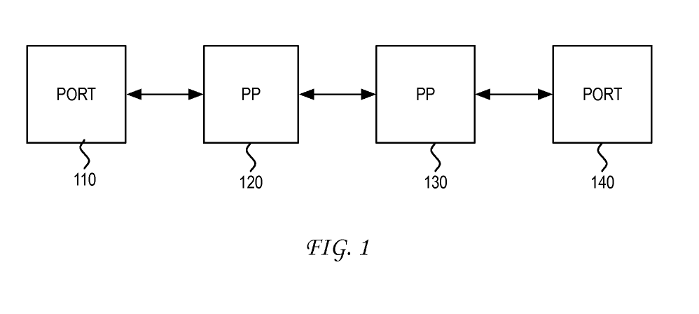

FIG. 1 illustrates an example application of the use of a patch panel in facilitating a network link. In this typical topology, a link between a first port 110 in a first network device and a second port 140 in a second network device is facilitated by a pair of patch panels 120 and 130. In a typical scenario, the connection between patch panels 120 and 130 is the major segment of the link (e.g., 90 m of a 100 m link). This connection can reside inside walls and may not be visible. Coupling of port 110 to the front panel of patch panel 120 and the coupling of port 140 to the front panel of patch panel 130 enables a quick interconnection between two network devices.

In an environment such as a data center that houses thousands or tens of thousands of servers, switches, routers, etc., large numbers of patch panels are required for proper cable management. Conventional patch panel technology implemented in today's installations is fairly limited.

In one example, a conventional patch panel can include an infrared sensor at each patch panel port to detect whether a connection has been made at that patch panel port. Here, the insertion of a terminated cable into a front connector port of a patch panel would obstruct the line-of-sight path between an infrared source and an infrared detector. The reading of the infrared detector can then be used to indicate whether or not a terminated cable has been inserted into the patch panel port. A local display can then be used to identify which of the ports have or do not have a terminated cable inserted.

In another example, a patch panel can be designed to include software and a network interface card (NIC) that enables the patch panel to be managed remotely. Notwithstanding such remote management features in the patch panel, the information that can be retrieved from the patch panel is still limited by that which can be obtained from a sensor that is external to the data communication link.

In the present invention, it is recognized that the provision of new functionality into a patch panel would have a commensurately large effect in the administration, operation, maintenance and provisioning functionality within the network infrastructure. This results due to the wide-spread adoption of such interconnection devices in various infrastructure applications. Any impact on functionality in such common interconnection devices therefore provides large value to the end user/IT professionals.

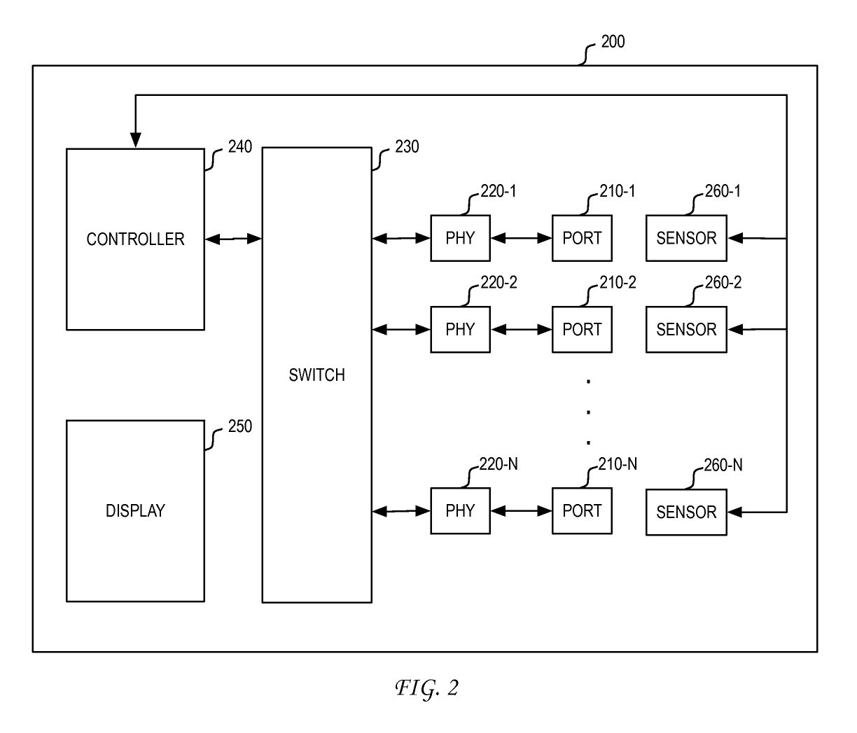

It is a feature of the present invention that the functionality in a patch panel can be augmented through the inclusion of physical layer device (PHY) technology into the patch panel. FIG. 2 illustrates an embodiment of such a patch panel management system that includes PHY technology in the patch panel ports.

As illustrated, patch panel management system 200 includes a plurality of patch panel ports 210-n. Coupled to each of the plurality of patch panel ports 210-n is a corresponding plurality of PHYs 220-n. PHYs 220-n are each coupled to switch 230, which in turn is coupled to controller 240. In general, switch 230 can represent any multiplexer, switching circuit, or the like that facilitates a connection between controller 240 and any of the patch panel PHYs 220-n.

Unlike conventional patch panels, the patch panel management system of the present invention adds PHY technology such that additional properties of the communication channel can be reported using PHY cable diagnostic techniques. For example, PHY 220-1 can be designed to examine the communication channel of the communication cable coupled to port 210-1. Various properties of the communication channel can be examined, such as whether or not a link is active, the length of the communication cable, the type of communication cable, the existence and/or location of a fault in the cable, etc.

As would be appreciated, PHY technology used in transmission systems such as a switch, server, etc. includes diagnostic capabilities that can measure electrical properties of the communication cable. In the present invention, the PHYs 220-n that are included in patch panel management system 200 need not be full-featured PHYs. Rather, PHYs 220-n can represent reduced-functionality PHYs that incorporate functionality focused on channel diagnostics. As would be appreciated, as PHYs 220-n function largely as pass-through devices instead of as a link partner, much of the data communication functionality (e.g., PHY/MAC interface) need not be included in patch panel PHYs 220-n.

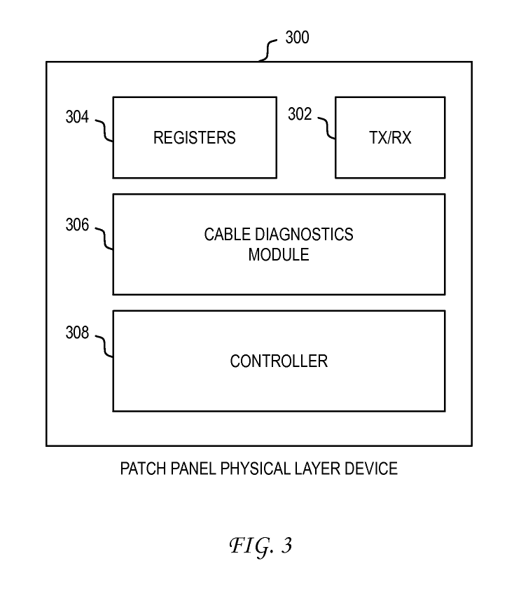

FIG. 3 illustrates one example of an embodiment of a reduced-functionality PHY that can be used in a patch panel management system of the present invention. As illustrated, patch panel PHY 300 includes transmit/receive (TX/RX) module 302, registers 304, cable diagnostic module 306, and controller 308.

In general, TX/RX module 302 facilitates a communication interface between cable diagnostic module 306 and the signals carried on the communication cable coupled to the corresponding patch panel port 210-n. In one embodiment, cable diagnostic module 306 performs the cable diagnostics non-obtrusively. In an alternative embodiment, the cable diagnostic module performs the cable diagnostics in cooperation with an active data communication process that is occurring between two link partners. As would be appreciated, the specific mechanism and corresponding method by which cable diagnostic module 306 operates in the context of an active communication link would be implementation dependent.

In general, cable diagnostics performed by cable diagnostics module 306 is performed under the control of controller 308. Cable diagnostics module 306 can be designed to generate and transmit a signal (e.g., pulses) into the communication cable coupled to the patch panel port, and to measure a return or reflected signal received by TX/RX module 302. Signals received by TX/RX module 302 are then processed by cable diagnostic module 306 to determine various cabling parameters reflective of communication channel characteristics.

A simple example of a cabling parameter that can be identified is whether a communication channel is active. This can be determined by whether the patch panel PHY detects any link energy on the patch panel port.

In another example, the patch panel PHY can determine a cable length through time-domain reflectometry (TDR), which relies on the transmission of a pulse into the communication cable and the measurement of returned reflections of the transmitted pulse. The cable length or a distance to a cable fault can be determined from the time difference between the transmitted and reflected pulse. Cable failures and the location of such failures can be detected using TDR.

In yet another example, the patch panel PHY measurements can be used to determine a type of cabling (e.g., Category 5, 6, 7, etc. Ethernet cabling) that is coupled to the patch panel port. As described in greater detail in U.S. Pat. No. 7,664,972, entitled “System and Method for Controlling Power Delivered to a Powered Device Based on Cable Characteristics,” which is incorporated herein by reference in its entirety, PHY measurements such as crosstalk and insertion loss can be used to determine a type of structured Ethernet cabling.

The measurements taken by patch panel PHY 300 can be stored in memory registers 304. The information stored in memory registers 304 can then be retrieved by controller 240 of patch panel management system 200.

As noted above, controller 240 is coupled to PHYs 220-n via switch 230. Switch 230 enables controller 240 to communicate with and activate the cable diagnostic module in any of PHYs 220-n. In one embodiment, the selective activation can be based on a polling scheme implemented by controller 240 that periodically diagnoses patch panel ports 210-n. Of course, manual activation of a particular cable diagnostic module in a patch panel PHY can also be performed by IT personnel.

Regardless of the particular frequency of diagnosis of patch panel ports 210-n, controller 240 is designed to retrieve diagnostic measurement data that enables a determination of various cabling parameters for ports 210-n. The determined cabling parameters can then be displayed on display 250 for analysis by a user/IT professional. This display of cabling information facilitates effective operation, administration, maintenance and provisioning efforts.

As FIG. 2 further illustrates, a plurality of sensors 260-n, which are respectively associated with patch panel ports 210-n, can also be included in patch panel management system 200 to obtain further patch panel port information. Sensors 260-n can be coupled directly to controller 240, or can be accessed via controller 240 via switch 230. In one example, sensors 260-n can be RFID sensors that are designed to retrieve RFID information from RFID tags on the patch cords.

In another example, sensors 260-n can represent a loop of wire that is integrated into the patch panel port connector. This loop of wire can be designed to detect a tone frequency using a non-invasive inductive pick up. IT personnel can use this loop of wire for diagnostic and management capabilities. For example, IT personnel can use the loop of wire to identify a specific communication cable when a tone is generated on the other end of the communication cable.

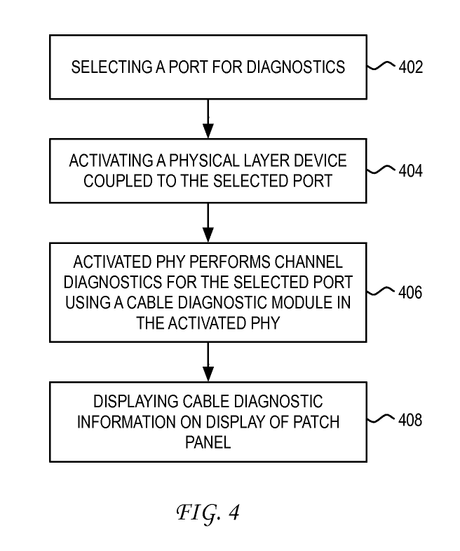

Having described a general framework for an intelligent patch panel management system, reference is now made to the flowchart of FIG. 4 to illustrate a process according to the present invention. As illustrated, the process begins at step 402 where a particular patch panel port 210-n is selected for diagnostics. As noted, the selection of a particular patch panel port 210-n can be performed in the context of a polling scheme that performs diagnostics on the plurality of patch panel ports 210-n in patch panel management system 200.

After a particular patch panel port 210-n is selected, PHY 220-n coupled to the selected patch panel port 210-n is then activated at step 404. Activation of the patch panel PHY 220-n can be performed by controller 240 in the patch panel management system 200. Controller 240 activates the patch panel PHY 220-n through a connection facilitated by switch 230.

Next, at step 406, the cable diagnostic module in the activated patch panel PHY 220-n performs channel diagnostics on the associated patch panel port 210-n. As the primary purpose of the activated patch panel PHY 220-n is to perform channel diagnostics and not data communication, patch panel PHY 220-n need not be a full-featured PHY. As such, the patch panel PHY 220-n can incorporate limited functionality, thereby producing significant diagnostic functionality with little additional cost.

The particular diagnostics performed by patch panel PHY 220-n is implementation dependent. In one application, the cable diagnostic module in patch panel PHY 220-n can be designed to generate cable type and length information. Here, it should be noted, that the diagnostics performed by patch panel PHY 220-n can be supplemented by additional sensors 260-n that are also associated with a patch panel port. These additional sensors 260-n can be designed to perform additional sensor measurements (e.g., infrared, RFID, etc.) that are external to those related to the transmission of signals in the communication cable.

The result of the various diagnostics implemented by the patch panel PHY 220-n and optional additional sensors 260-n can then be displayed on display 250 of patch panel management system 200 at step 408. This display of such diagnostic information can greatly assist the IT professional in ensuring that the desired connectivity is properly implemented by the patch panel management system.

One of the benefits of incorporating PHY diagnostic functionality into the patch panel management system is the enabling of highly granular link diagnostics. By leveraging the sophisticated diagnostic capabilities that are incorporated into modern PHYs, the IT professional can monitor the various segments of a link. This reduces troubleshooting by quickly identifying faulty cabling or low performing link segments.

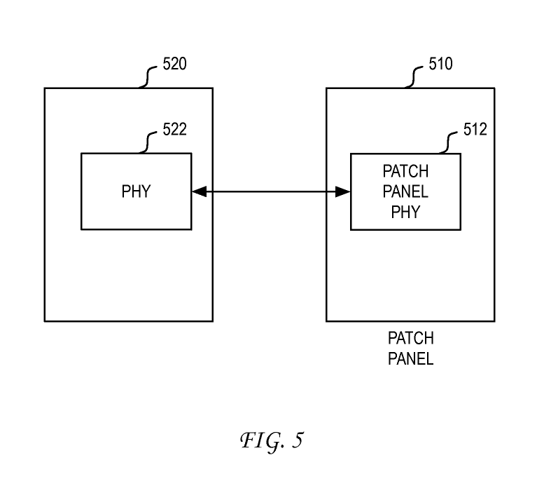

In one embodiment, the patch panel PHY can be designed to report cable diagnostic information to the controller instead of performing the actual diagnostic measurements itself. FIG. 5 illustrates an example of such an embodiment. As illustrated, patch panel PHY 512 in patch panel 510 is connected to PHY 512 in network device 520 (e.g., switch, server, etc.). In this arrangement, full-featured PHY 522 can be designed to perform the channel diagnostics and report the results of such channel diagnostics to patch panel PHY 512. Patch panel PHY 512 can then report the received channel diagnostics to the controller in the patch panel management system for subsequent display. As would be appreciated, this embodiment of the present invention can further reduce the complexity of patch panel PHY 512, thereby saving additional cost.

In one embodiment, the patch panel can also act as a midspan power sourcing equipment for power over Ethernet (PoE). In this arrangement, the patch panel PHYs in the enhanced patch panel management system can also be used to facilitate cable diagnostics for PoE. For example, the PoE portion of the cable diagnostics can be used to identify a cable length and/or cable type, which can be used to determine a cable resistance. This cable resistance can then be used to determine PoE parameters for the PoE link, such as the voltage drop across the cable, the power loss of the cable, etc. These PoE parameters can then be used to determine and/or adjust a power budget (e.g., current limit) that is applied by a power sourcing equipment to a powered device coupled to the port.

It should be noted that the principles of the present invention can be applied to all types of cabling. For example, the principles of the present invention can be applied to structured/unstructured cabling, shielded/unshielded cabling, etc. The principles of the present invention would also extend to optical cabling.

These and other aspects of the present invention will become apparent to those skilled in the art by a review of the preceding detailed description. Although a number of salient features of the present invention have been described above, the invention is capable of other embodiments and of being practiced and carried out in various ways that would be apparent to one of ordinary skill in the art after reading the disclosed invention, therefore the above description should not be considered to be exclusive of these other embodiments. Also, it is to be understood that the phraseology and terminology employed herein are for the purposes of description and should not be regarded as limiting.

What is claimed is:

1. A patch panel management system, comprising:
a plurality of ports, each of said plurality of ports being configured for coupling to a communication cable;
a plurality of physical layer devices that are respectively coupled to said plurality of ports, each of said plurality of physical layer devices having a cable diagnostic module for analyzing an associated port;
a switch that is coupled to each of said plurality of physical layer devices; and
a controller that is coupled to said switch, said controller being designed to select an identified one of said plurality of physical layer devices and to activate a cable diagnostic module in said identified physical layer device, said activated cable diagnostic module diagnosing a cabling parameter of a port coupled to said identified physical layer device.

2. The system of claim 1, wherein said cabling parameter is whether a communication channel is active.

3. The system of claim 1, wherein said cabling parameter is a cable length.

4. The system of claim 1, wherein said cabling parameter is a cable type.

5. The system of claim 1, wherein said cabling parameter is an existence or a location of a cable fault.

6. The system of claim 1, further comprising a display that displays, for a plurality of ports, a communication cable connection status and one or more communication cable properties.

7. A patch panel management system, comprising:
a plurality of ports, each of said plurality of ports being configured for coupling to a communication cable;
a plurality of physical layer devices that are respectively coupled to said plurality of ports;
a switch that is coupled to each of said plurality of physical layer devices;
a controller coupled to said switch, said controller being designed to communicate with said plurality of physical layer devices via said switch; and
a display that displays, for a first port in said plurality of ports, a communication cable connection status and one or more communication cable properties, wherein at least one of said one or more communication cable properties for said first port is based on information received from a remote link partner physical layer device that is coupled to said first port via a communication cable.

8. The system of claim 7, wherein said communication cable connection status is whether a communication channel is active.

9. The system of claim 7, wherein said one or more communication cable properties is a cable length.

10. The system of claim 7, wherein said one or more communication cable properties is a cable type.

11. The system of claim 7, wherein said one or more communication cable properties is an existence or a location of a cable fault.

12. A method in a patch panel management system, said patch panel management system including a plurality of ports, each of said plurality of ports being configured for coupling to a communication cable, a plurality of physical layer devices that are respectively coupled to said plurality of ports, a switch that is coupled to each of said plurality of physical layer devices, and a controller that is coupled to said switch, the method comprising:
connecting said controller, via said switch, to a first physical layer device coupled to a first port in said plurality of ports;
activating, by said controller, a cable diagnostic module in said first physical layer device;
diagnosing, by said activated cable diagnostic module, one or more cabling parameters of said first port; and
displaying, in a display of said patch panel management system, cabling information based on said diagnosis.

13. The method of claim 12, wherein said displaying comprises displaying a communication cable connection status that identifies whether a communication channel is active.

14. The method of claim 12, wherein said displaying comprises displaying a cable length.

15. The method of claim 12, wherein said displaying comprises displaying a cable type.

16. The method of claim 12, wherein said displaying comprises displaying an existence or a location of a cable fault.

17. A patch panel management system used in providing power over Ethernet, comprising:
a plurality of ports, each of said plurality of ports being configured for coupling to a communication cable and for providing power over said communication cable to a remote device;
a plurality of physical layer devices that are respectively coupled to said plurality of ports, each of said plurality of physical layer devices having a cable diagnostic module for analyzing an associated port; and
a controller that is designed to activate a cable diagnostic module in a physical layer device for diagnosing of a cabling parameter of a port, said diagnosed cabling parameter enabling an adjustment of a power budget for said diagnosed port.

18. The patch panel management system of claim 17, wherein said diagnosed cabling parameter is a length of a communication cable.

19. The patch panel management system of claim 17, wherein said diagnosed cabling parameter is a type of a communication cable.
